(19) United States
(12) Patent Application Publication
(10) Pub. No.: US 2025/0351689 A1
(43) Pub. Date: Nov. 13, 2025

(54) DISPLAY PANEL AND DISPLAY DEVICE

(71) Applicants: Wuhan Tianma Micro-Electronics Co., Ltd., Wuhan (CN); Wuhan Tianma Micro-Electronics Co., Ltd. Shanghai Branch, Shanghai (CN)

(72) Inventors: Dan DONG, Wuhan (CN); Shaowei LIU, Wuhan (CN)

(21) Appl. No.: 18/805,926

(22) Filed: Aug. 15, 2024

(30) Foreign Application Priority Data
May 13, 2024 (CN) 202410592896.0

(51) Int. Cl. H10K 59/131; H10K 59/124

(52) U.S. Cl. CPC H10K 59/131; H10K 59/124

(57) ABSTRACT

A display panel and a display device are provided. The display panel includes: a first display area; a second display area at least partially surrounds the first display area and having light transmittance smaller than light transmittance of the first display area; light-emitting elements including first light-emitting elements in the first display area; pixel circuits including first pixel circuits in the second display area; first connecting lines; and first filling lines. The first pixel circuits are used to drive the first light-emitting elements to emit light. The first light-emitting elements and the first pixel circuits are electrically connected through the first connecting lines. The first filling lines are disposed in a layer same as the first connecting lines, and are located between at least a portion of two adjacent first connecting lines. An extension direction of the first filling lines intersects with an extension direction of the first connecting lines.

### CROSS-REFERENCE TO RELATED APPLICATION

This application claims the priority of Chinese Patent Application No. 202410592896.0, filed on May 13, 2024, the content of which is incorporated herein by reference in its entirety.

### TECHNICAL FIELD

The present disclosure generally relates to the field of display technology and, more particularly, relates to a display panel and a display device.

### BACKGROUND

With the continuous development of display technology, to enhance visual experience, people have an increasingly higher pursuit of screen-to-body ratio of display devices.

In some display devices, a part of a display area in a display panel has a high light transmittance, and a photosensitive element can be set under this part of the display area such that external light can pass through this partial display area to reach the photosensitive element to realize corresponding functions such as front camera or infrared sensing.

In the above scheme, to improve the light transmittance of this part of the display area, pixel circuits of light-emitting elements used for this part of the display area are usually disposed in another part of the display area, and the light-emitting elements in the part of the display area and the corresponding pixel circuits are electrically connected through wires. However, the presence of these wires will cause the diffraction of light in different directions in the part of the display area to be different, affecting the display effect.

### SUMMARY

One aspect of the present disclosure provides a display panel. The display panel includes: a first display area and a second display area; light-emitting elements including first light-emitting elements disposed in the first display area; pixel circuits including first pixel circuits disposed in the second display area; first connecting lines; and first filling lines. The second display area at least partially surrounds the first display area and light transmittance of the first display area is larger than light transmittance of the second display area. The first pixel circuits are used to drive the first light-emitting elements to emit light. One first light-emitting element and one corresponding first pixel circuit are electrically connected through one corresponding first connecting lines. The first filling lines are disposed in a layer same as the first connecting lines, and are located between at least a portion of two adjacent first connecting lines. An extension direction of the first filling lines intersects with an extension direction of the first connecting lines.

Another aspect of the present disclosure provides a display device. The display device includes a display panel. The display panel includes: a first display area and a second display area; light-emitting elements including first light-emitting elements disposed in the first display area; pixel circuits including first pixel circuits disposed in the second display area; first connecting lines; and first filling lines. The second display area at least partially surrounds the first display area and light transmittance of the first display area is larger than light transmittance of the second display area. The first pixel circuits are used to drive the first light-emitting elements to emit light. One first light-emitting element and one corresponding first pixel circuit are electrically connected through one corresponding first connecting lines. The first filling lines are disposed in a layer same as the first connecting lines, and are located between at least a portion of two adjacent first connecting lines. An extension direction of the first filling lines intersects with an extension direction of the first connecting lines.

Other aspects or embodiments of the present disclosure can be understood by those skilled in the art in light of the description, the claims, and the drawings of the present disclosure.

### BRIEF DESCRIPTION OF THE DRAWINGS

The following drawings are merely examples for illustrative purposes according to various disclosed embodiments and are not intended to limit the scope of the present disclosure.

FIG. 1 illustrates an exemplary display panel consistent with various disclosed embodiments in the present disclosure.

FIG. 2 illustrates an enlarged view of a part of an exemplary display panel consistent with various disclosed embodiments in the present disclosure.

FIG. 3 illustrates an enlarged top view of a first connection wire and a first filling wire of an exemplary display panel consistent with various disclosed embodiments in the present disclosure.

FIG. 4 illustrates another enlarged top view of a first connection wire and a first filling wire of an exemplary display panel consistent with various disclosed embodiments in the present disclosure.

FIG. 5 illustrates an enlarged top view of a second connection wire and a second filling wire of an exemplary display panel consistent with various disclosed embodiments in the present disclosure.

FIG. 6 illustrates another enlarged top view of a second connection wire and a second filling wire of an exemplary display panel consistent with various disclosed embodiments in the present disclosure.

FIG. 7 illustrates a cross-sectional view of an exemplary display panel consistent with various disclosed embodiments in the present disclosure.

FIG. 8 illustrates another enlarged top view of a connection wire and a filling wire of an exemplary display panel consistent with various disclosed embodiments in the present disclosure.

FIG. 9 illustrates an enlarged top view of a first connection wire and a second connection wire of an exemplary display panel consistent with various disclosed embodiments in the present disclosure.

FIG. 10 illustrates an enlarged top view of a first filling wire and a second filling wire of an exemplary display panel consistent with various disclosed embodiments in the present disclosure.

FIG. 11 illustrates another enlarged top view of a first connection wire and a second connection wire of an exemplary display panel consistent with various disclosed embodiments in the present disclosure.

FIG. 12 illustrates a cross-sectional view of another exemplary display panel consistent with various disclosed embodiments in the present disclosure.

FIG. 13 illustrates an enlarged top view of a third connection wire of an exemplary display panel consistent with various disclosed embodiments in the present disclosure.

FIG. 14 illustrates a top view of an arrangement structure of first filling wires of an exemplary display panel consistent with various disclosed embodiments in the present disclosure.

FIG. 15 illustrates another top view of an arrangement structure of first filling wires of an exemplary display panel consistent with various disclosed embodiments in the present disclosure.

FIG. 16 illustrates an enlarged view of a part of an exemplary display panel consistent with various disclosed embodiments in the present disclosure.

FIG. 17 illustrates another enlarged view of a part of an exemplary display panel consistent with various disclosed embodiments in the present disclosure.

FIG. 18 illustrates another enlarged view of a part of an exemplary display panel consistent with various disclosed embodiments in the present disclosure.

FIG. 19 illustrates another exemplary display panel consistent with various disclosed embodiments in the present disclosure.

FIG. 20 illustrates another cross-sectional view of an exemplary display panel consistent with various disclosed embodiments in the present disclosure.

FIG. 21 illustrates an exemplary display device consistent with various disclosed embodiments in the present disclosure.

### DETAILED DESCRIPTION

Reference will now be made in detail to exemplary embodiments of the disclosure, which are illustrated in the accompanying drawings. Hereinafter, embodiments consistent with the disclosure will be described with reference to drawings. In the drawings, the shape and size may be exaggerated, distorted, or simplified for clarity. Wherever possible, the same reference numbers will be used throughout the drawings to refer to the same or like parts, and a detailed description thereof may be omitted.

Further, in the present disclosure, the disclosed embodiments and the features of the disclosed embodiments may be combined under conditions without conflicts. It is apparent that the described embodiments are some but not all of the embodiments of the present disclosure. Based on the disclosed embodiments, persons of ordinary skill in the art may derive other embodiments consistent with the present disclosure, all of which are within the scope of the present disclosure.

Moreover, the present disclosure is described with reference to schematic diagrams. For the convenience of descriptions of the embodiments, the cross-sectional views illustrating the device structures may not follow the common proportion and may be partially exaggerated. Besides, those schematic diagrams are merely examples, and not intended to limit the scope of the disclosure. Furthermore, a three-dimensional (3D) size including length, width, and depth should be considered during practical fabrication.

In the present disclosure, relational terms such as first and second are only used to distinguish one entity or operation from another entity or operation, and do not necessarily require or imply any such actual relationship between these entities or operations or order. Moreover, the terms “including”, “comprising” or any other variants thereof are intended to cover non-exclusive inclusion, such that a process, method, article, or device that includes a series of elements includes not only those elements, but also those that are not explicitly listed or also include elements inherent to this process, method, article or equipment. If there are no more restrictions, the elements defined by the sentence “including . . . ” do not exclude the existence of other same elements in the process, method, article, or equipment that includes the elements.

It should be understood that when describing the structure of a component, when a layer or region is referred to as being “on” or “above” another layer or another region, the layer or region may be directly on the other layer or region, or indirectly on the other layer or region, for example, layers/components between the layer or region and another layer or another region. And, for example, when the component is reversed, the layer or region may be “below” or “under” the other layer or region. In the present disclosure, the term “electrical connection” refers to that two components are directly electrically connected with each other, or the two components are electrically connected via one or more other components.

In a display panel in existing technology, wires connecting light-emitting elements and pixel circuits in different parts of a display area cause the diffraction of light in different directions in the parts of the display area to be different, affecting the display effect.

The present disclosure provides a display panel and a display device to at least partially alleviate the above problems. In the present disclosure, a plurality of first filling lines may be disposed between at least a portion of two adjacent first connecting lines (i.e., wires for connecting light emitting elements and pixel circuits in different parts of a display area). Therefore, the difference in the diffraction of light in different directions of the display panel may be reduced, and the display uniformity and the display effect may be improved. The display panel in the present disclosure may include a first display area and a second display area, and also include light emitting elements, pixel circuits, a plurality of first connecting lines, and a plurality of first filling lines. The light emitting elements may include first light emitting elements arranged in the first display area, and the pixel circuits may include first pixel circuits arranged in the second display area. One first pixel circuit may be used to drive one corresponding first light emitting element to emit light, and one first light emitting element may be electrically connected to one corresponding first pixel circuit through one corresponding first connecting line of the plurality of first connecting line. The plurality of first filling lines may be arranged in the same layer as the plurality of first connecting lines and one first filling line may be located between at least a portion of two adjacent first connecting lines, and the extension direction of the first filling line intersects with the extension direction of the first connecting line.

In the present disclosure, the plurality of first filling lines may be arranged between at least a portion of two adjacent first connecting lines, and the extension direction of the plurality of first filling lines may intersect with the extension direction of the first connecting lines. Therefore, the plurality of first filling lines may balance the phase differences in different directions caused by the plurality of first connecting lines, reduce the differences in light diffraction of the display panel in different directions, improve display uniformity, and enhance display effects.

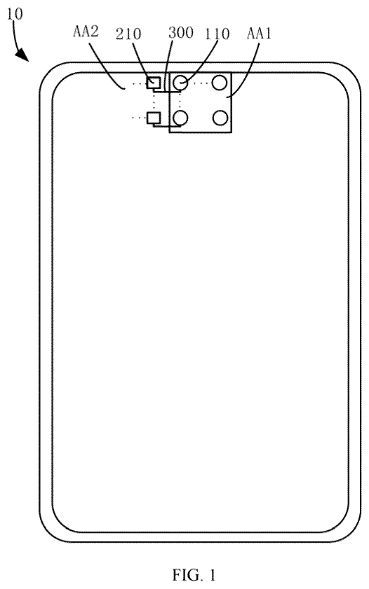

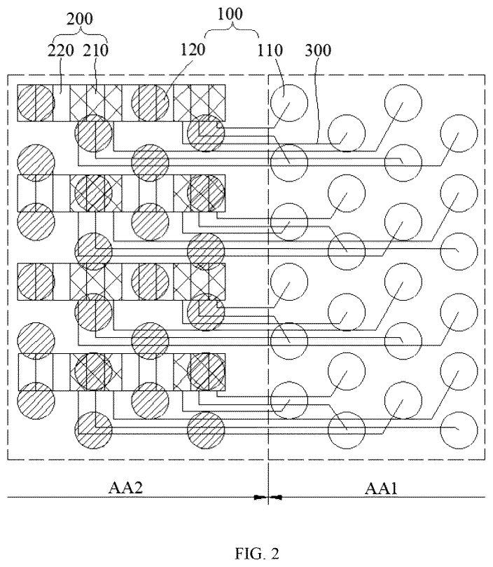

The present disclosure provides a display panel. As shown in FIG. 1 which illustrates an exemplary display panel and FIG. 2 which illustrates a partially enlarged view of the display panel, in one embodiment, the display panel 10 may include a first display area AA1 and a second display area AA2.

The second display area AA2 may at least partially surround the first display area AA1, and the transmittance of the first display area AA1 may be larger than the transmittance of the second display area AA2. The specific shapes, sizes, relative position relationship, etc. of the first display area AA1 and the second display area AA2 are not limited. For example, in one embodiment, the second display area AA2 may be located on at least one side of the first display area AA1 in a certain direction. Or, in another embodiment, the second display area AA2 may be located around the first display area AA1 on multiple sides of the periphery of the first display area AA1. In some embodiments, the display panel 10 may also include a non-display area, and the non-display area may be arranged around the first display area AA1 and the second display area AA2.

As shown in FIG. 1 and FIG. 2, the display panel 10 may further include light-emitting elements 100, pixel circuits 200 and first connecting lines 300. The first light-emitting elements 110 may be disposed in the first display area AA1, and the first pixel circuits 210 may be disposed in the second display area AA2. One first pixel circuit 210 may be used to drive one corresponding first light-emitting element 110 to emit light. The first light-emitting elements 110 and the first pixel circuits 210 may be located in different display areas, and one first light-emitting element 110 may be electrically connected to one corresponding first pixel circuit 210 via one corresponding first connecting line 300, such that the corresponding first pixel circuit 210 is able to drive the first light-emitting element 110 to emit light. The first connecting line 300 may adopt a multi-segment structure.

The second display area AA2 of the display panel 10 may be also provided with second light-emitting elements 120 and second pixel circuits 220 for driving the second light-emitting elements 120 to emit light, and one second light-emitting element 120 may be electrically connected to one corresponding second pixel circuit 220.

The light transmittance of the first display area AA1 may be relatively large, and the first light-emitting elements 110 may be disposed in the first display area AA1, such that the first display area AA1 is able to display and transmit light at the same time. The first pixel circuits 210 for driving the first light-emitting elements 110 to emit light may be arranged in the second display area AA2, which reduces the wiring structure in the first display area AA1 and reduces the influence on the light transmittance of the first display area AA1. Therefore, the first display area AA1 may be able to better meet the light transmittance requirements of the photosensitive elements for the display panel 10, such that the photosensitive elements may be integrated on the back of the first display area AA1 to realize the under-screen light sensing function and improve the display uniformity of the display panel as a whole.

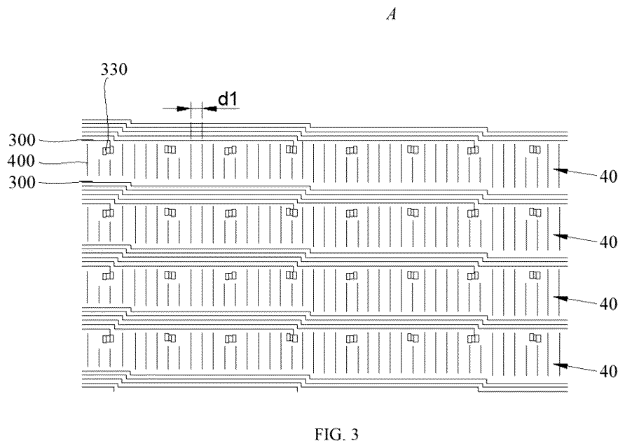

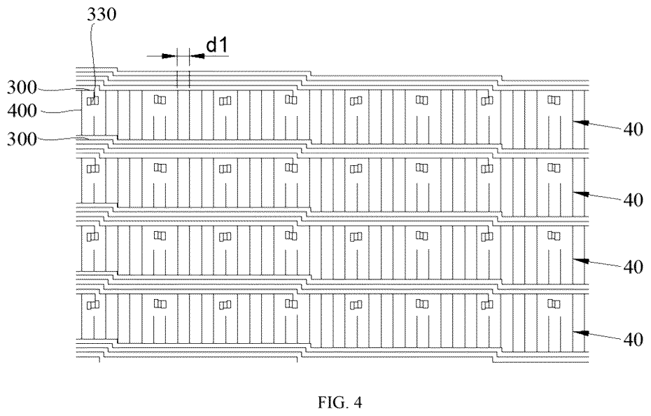

FIG. 3 is a schematic top view of an enlarged structure of the first connection lines 300 and first filling lines 400 in a display panel 10 provided in an embodiment of the present disclosure, and FIG. 4 is another schematic top view of an enlarged structure of the first connection lines 300 and the first filling line 400 in a display panel 10 provided in another embodiment of the present disclosure. To eliminate the problem that the light diffraction conditions of the first display area AA1 in different directions are different because of the existence of the first connection lines 300 to affect the display effect, as shown in FIG. 3 and FIG. 4, in one embodiment, the display panel 10 may further include the first filling lines 400, and the first filling lines 400 may be arranged in the same layer as the first connection lines 300 and located between at least a portion of two adjacent first connection lines 300. As shown in FIG. 3, in one embodiment, the first filling lines 400 may be spaced apart from the first connection lines 300 such that the first filling lines 400 are electrically insulated from the first connection lines 300. As shown in FIG. 4, in another embodiment, at least part of the first filling lines 400 may be electrically connected to the first connecting lines 300, such that the first filling lines 400 are connected in parallel with the first connecting lines 300 to reduce the voltage drop of the signal on the first connecting lines 300. Therefore, the driving effect of the first pixel circuits 210 and the display effect in the first display area AA1 may be improved. It should be noted that, as shown in FIG. 3 and FIG. 4, the first connecting lines 300 may be connected to different film layers via through holes 330. For example, the first connecting lines may be connected to the first light-emitting elements 110 via the through holes 330.

Among the multiple first connection lines 300, there may be the first filling lines 400 between at least two adjacent first connection lines 300. For example, there may be the first filling lines 400 between some adjacent first connection lines 300, and there may be no first filling line 400 between another part of adjacent first connection lines 300. The extension direction of the first filling lines 400 may intersect with the extension direction of the first connection lines 300. The angle at which the first filling lines 400 intersect with the first connection lines 300 may be an acute angle, a right angle, or an obtuse angle. The length of the first filling lines 400 may vary according to the different spacings between two adjacent first connection lines 300. The number and arrangement density of the first filling lines 400 are not limited here. The existence of the first filling lines 400 may balance the phase difference in different directions caused by the first connection lines 300, reduce the difference in the diffraction of light in different directions of the display panel 10, and improve the sensitivity of the photosensitive elements when there are the photosensitive elements in the first display area AA1.

In the present disclosure, the display panel 10 may be provided with the multiple first filling lines 400 between at least a portion of two adjacent first connecting lines 300, and the extension direction of the first filling lines 400 may intersect with the extension direction of the first connecting lines 300. Therefore, the first filling lines 400 may balance the phase difference in different directions caused by the first connection lines 300, reduce the difference in the diffraction of light in different directions of the display panel 10, improve display uniformity, and enhance the display effect.

According to the different setting positions and arrangement modes of the first filling lines 400, the first filling lines 400 may be arranged in groups. As shown in FIG. 3 and FIG. 4, in some embodiments, optionally, the display panel 10 may include a plurality of first filling line groups 40, and each first filling line group 40 may include a plurality of the first filling lines 400 that are adjacent to each other and arranged in parallel. That is, as shown in FIG. 3 and FIG. 4, a plurality of the first filling lines 400 located between the same two adjacent first connection lines 300 may be a group to form one first filling line group 40. The plurality of the first filling lines 400 in one same first filling line group 40 may be adjacent to each other and arranged in parallel. Therefore, the angles of intersection between the plurality of the first filling lines 400 in the same first filling line group 40 and the first connection lines 300 adjacent thereto may be also the same. In different first filling line groups 40, the numbers of the plurality of the first filling lines 400 in each group, the angles of intersection with the first connection lines 300 adjacent thereto, the arrangement density of the plurality of the first filling lines 400, etc. may be consistent or different from each other. In other embodiments, the first filling lines 400 may be divided into more or fewer different first filling line groups 40 according to other different regular ways, and the number of first filling lines 400 in each first filling line group 40 may also be different, which will not be described in detail here.

The multiple of the first filling lines 400 in one same first filling line group 40 may be adjacent to each other and arranged in parallel, such that there may be a certain gap between two adjacent first filling lines 400 in the same first filling line group 40. Based on the above embodiment, optionally, in one first filling line group 40, the spacing between any two adjacent first filling lines 400 may be d1, where 1 μm≤d1≤11 μm. Exemplarily, in a specific embodiment, the spacing d1 between any two adjacent first filling lines 400 in the same first filling line group 40 may be 1 μm, 1.6 μm, 2 μm, 3.4 μm, 5 μm, 8.7 μm, 10 μm, 10.2 μm, 11 μm, etc. The above values are only examples of the spacing d1 between any two adjacent first filling lines 400 in the same first filling line group 40. In actual products, the spacing d1 between any two adjacent first filling lines 400 in the same first filling line group 40 is not limited to the above values.

The multiple of the first filling lines 400 in the same first filling line group 40 may be arranged uniformly or unevenly, as shown in FIG. 3 and FIG. 4. In some embodiments, optionally, in one first filling line group 40, the spacing between any two adjacent first filling lines 400 may be approximately equal. That is, the arrangement density of the multiple of the first filling lines 400 in the same first filling line group 40 may be approximately equal everywhere, such that the multiple of the first filling lines 400 are arranged uniformly. In this way, the first filling lines 400 may reduce the difference in the diffraction of light in different directions of the display panel 10 more uniformly, which is more conducive to improving the display uniformity of the display panel 10.

As shown in Table 1 below, in one display panel in the existing technology, that is, one display panel not including the first filling lines 400 but using a polarizer (POL), relative to the bare lens, the relative grayscale of the local position of the diffracted image in the horizontal direction of the first display area AA1 is 10.62%, and the relative grayscale of the local position in the vertical direction is 9.54%. In a display panel using color filter on touch (CFOT), compared with the bare lens, the relative grayscale of the local position of the first display area AA1 in the horizontal direction after diffraction is 11.26%, and the relative grayscale of the local position in the vertical direction is 11.85%. It should be noted that the light diffraction is stronger when the relative grayscale value is larger.

TABLE 1
Relative diffraction strength of POL and CFOT technology

| | Relative | |
|---|---|---|
| | diffraction strength - | Relative diffraction |
| | Horizontal | strength - Vertical |
| | direction | direction |
| POL (AA1) | 10.62% | 9.54% |
| CFOT (AA1) | 11.26% | 11.85% |

In the above embodiments, as shown in FIG. 2, in the plurality of first filling line groups 40, the spacing between two adjacent first filling lines 400 may be one of 2 μm, 5 μm or 10 μm. When the spacing between two adjacent first filling lines 400 in the plurality of first filling line group 40 is 2 μm, relative to the bare lens, the relative grayscale of the local position of the diffraction image in the horizontal direction may be 11.14%, and the relative grayscale of the local position in the vertical direction may be 10.59%. When the spacing between two adjacent first filling lines 400 in the plurality of first filling line group 40 is 5 μm, relative to the bare lens, the relative grayscale of the local position of the diffraction image in the horizontal direction may be 11.23%, and the relative grayscale of the local position in the vertical direction may be 11.11%. When the spacing between two adjacent first filling lines 400 in the plurality of first filling line groups 40 is 10 μm, relative to the bare lens, the relative grayscale of the local position of the diffraction image in the horizontal direction may be 11.22%, and the relative grayscale of the local position in the vertical direction may be 11.45%.

TABLE 2
Relative diffraction strength after adding the first filling lines

| | Relative diffraction | Relative diffraction |
|---|---|---|
| | strength - | strength - Vertical |
| | Horizontal direction | direction |
| POL (AA1) | 10.62% | 9.54% |
| CFOT (AA1) | 11.26% | 11.85% |
| CFOT + first filling lines | 11.22% | 11.45% |
| with 10 μm pitch (AA1) | | |
| CFOT + first filling lines | 11.23% | 11.11% |
| with 5 μm pitch (AA1) | | |
| CFOT + first filling lines | 11.14% | 10.59% |
| with 2 μm pitch (AA1) | | |

From the above, it can be seen that no matter the spacing between two adjacent first filling lines 400 in the plurality of first filling line groups 40 is 2 μm, 5 μm or 10 μm, relative to the bare lens, the difference in the relative grayscale of the local position of the image in the horizontal direction after diffraction and the relative grayscale of the local position of the image in the vertical direction after diffraction may be both reduced, indicating that the difference in the diffraction conditions of light in the horizontal and vertical directions may be reduced, thereby improving the display uniformity of the display panel 10.

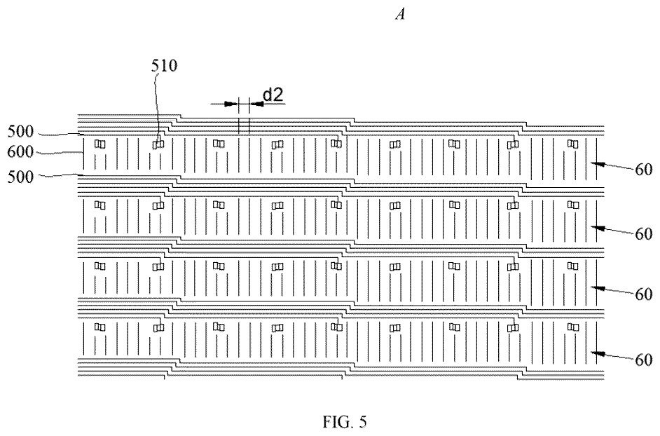

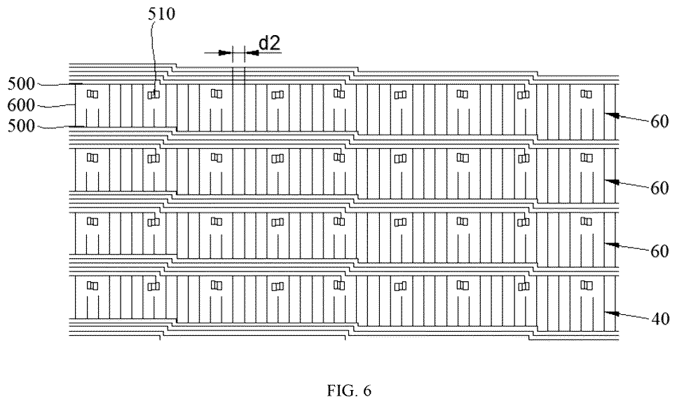

In one embodiment shown in FIG. 5 and FIG. 6, the display panel 10 may further include a plurality of second connection lines 500 and a plurality of second filling lines 600. As shown in FIG. 5 and FIG. 6, the plurality of second connection lines 500 may be connected to different film layers via through holes 510. For example, the plurality of second connection lines 500 may be connected to the first connection lines 300 via the through holes 510. Similarly, as shown in FIG. 5, in one embodiment, the plurality of second filling lines 600 may be electrically insulated from the plurality of second connection lines 500. As shown in FIG. 6, in another embodiment, the plurality of second filling lines 600 may also be electrically connected to the plurality of second connection lines 500.

To eliminate the problem that the light diffraction conditions of the first display area AA1 in different directions are different because of the existence of the plurality of second connection lines 500 affecting the display effect, the display panel 10 may further include the plurality of second filling lines 600. The plurality of second filling lines 600 may be arranged in the same layer as the plurality of second connection lines 500 and may be located between at least two adjacent second connection lines 500. That is, among the plurality of second connection lines 500, at least two adjacent second connection lines 500 may be provided with the plurality of second filling lines 600. For example, the plurality of second filling lines 600 may be provided between some of the adjacent second connection lines 500, and no second filling line 600 may exist between another part of the adjacent second connection lines 500. The extension direction of the plurality of second filling lines 600 may intersect with the extension direction of the plurality of second connecting lines 500. The angle at which the plurality of second filling lines 600 intersects with the plurality of second connecting lines 500 may be an acute angle, a right angle, or an obtuse angle. The length of the plurality of second filling lines 600 may vary according to the distance between two adjacent second connecting lines 500. The number and arrangement density of the plurality of second filling lines 600 are not limited here. The existence of the plurality of second filling lines 600 may balance the phase difference in different directions caused by the plurality of second connecting lines 500, and reduce the difference in the diffraction of light of the display panel 10 in different directions.

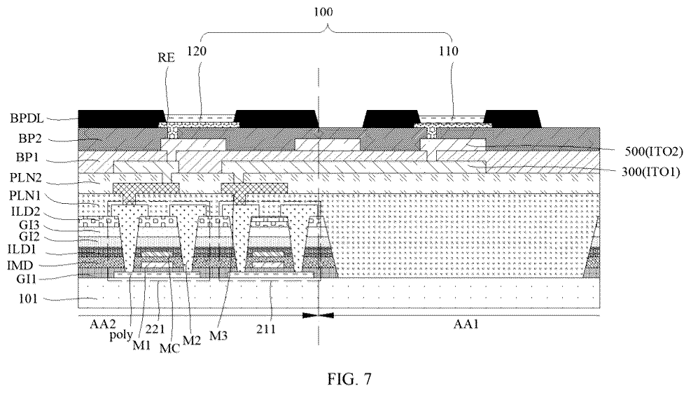

In one embodiment shown in FIG. 7 which is a cross-sectional view of an exemplary display panel 10, the display panel 10 may further include a substrate 101, a low-temperature polysilicon active layer poly, a first gate insulating layer GI1, a first metal layer M1, a capacitor insulating layer IMD, a capacitor metal layer MC, a first interlayer insulating layer ILD1, a second gate insulating layer GI2, a third gate insulating layer GI3, a second interlayer insulating layer ILD2, a second metal layer M2, a third metal layer M3, a first planarization layer PLN1, a second planarization layer PLN2, a first insulating layer BP1, a second insulating layer BP2, a first transparent conductive layer ITO1, a second transparent conductive layer ITO2, an anode RE, and a black pixel definition layer BPDL.

The substrate 101 may at least include a substrate, for example, may include a substrate and a buffer layer. The first gate insulating layer GI1, the capacitor insulating layer IMD, the first interlayer insulating layer ILD1, the second gate insulating layer GI2, the third gate insulating layer GI3, the second interlayer insulating layer ILD2, the first planarizing layer PLN1, the second planarizing layer PLN2, the first insulating layer BP1, the second insulating layer BP2 and the black pixel definition layer BPDL may be sequentially stacked on the substrate 101. The low-temperature polysilicon active layer poly may be located between the substrate 101 and the first gate insulating layer GI1. The first metal layer M1 may be located between the first gate insulating layer GI1 and the capacitor insulating layer IMD. The capacitor metal layer MC may be located between the capacitor insulating layer IMD and the first interlayer insulating layer ILD1. The second metal layer M2 may be located between the second interlayer insulating layer ILD2 and the first planarizing layer PLN1. The second metal layer M2 may be provided with metal through holes to be electrically connected to the low-temperature polysilicon active layer poly. The third metal layer M3 may be located between the first planarizing layer PLN1 and the second planarizing layer PLN2, and the third metal layer M3 may be provided with metal through holes to be electrically connected to the second metal layer M2. The first transparent conductive layer ITO1 may be located between the second planarization layer PLN2 and the first insulating layer BP1, and the first transparent conductive layer ITO1 may be provided with through holes to be electrically connected to the third metal layer M3. The second transparent conductive layer ITO2 may be located between the first insulating layer BP1 and the second insulating layer BP2, and the second transparent conductive layer ITO2 may be electrically connected to the first transparent conductive layer ITO1 via through holes.

The first connection lines 300 and the first filling lines 400 may be located in the first transparent conductive layer ITO1, and the plurality of second connection lines 500 and the plurality of second filling lines 600 may be located in the second transparent conductive layer ITO2. The black pixel definition layer BPDL may define pixel ports, and the light emitting elements 100 may be located in the pixel ports. The pixel ports may include first pixel ports and second pixel ports. The first pixel ports may be located in the first display area AA1, and the second pixel ports may be located in the second display area AA2. The first light emitting elements 110 may be located in the first pixel ports, and the second light emitting elements 120 may be located in the second pixel ports. One first pixel circuit 210 may include a first low-temperature polysilicon transistor 211, and one second pixel circuit 220 may include a second low-temperature polysilicon transistor 221. One first light emitting element 110 may be electrically connected to one corresponding second connection line 500 via the anode RE. Based on the above connection relationship, the first low-temperature polysilicon transistor 211 may be connected to the first light emitting element 110 via the first connection line 300, the second connection line 500 and the anode RE, such that the first pixel circuit 210 is electrically connected to the first light emitting element 110.

The plurality of second connection lines 500 may be electrically connected to the first connection lines 300, the first light emitting elements 110 and the first pixel circuits 210 corresponding thereto may be electrically connected via the first connection lines 300 and the second connection lines 500, and the second filling lines 600 may be disposed in the same layer as the second connection lines 500 and located between at least a portion of two adjacent second connection lines 500. In the thickness direction of the display panel 10, the second connection lines 500 and the first connection lines 300 may be disposed in different film layers respectively, and the second connection lines 500 may be electrically connected to the first connection lines 300, such that the first light emitting elements 110 and the first pixel circuits 210 corresponding thereto are electrically connected via the first connection lines 300 and the second connection lines 500.

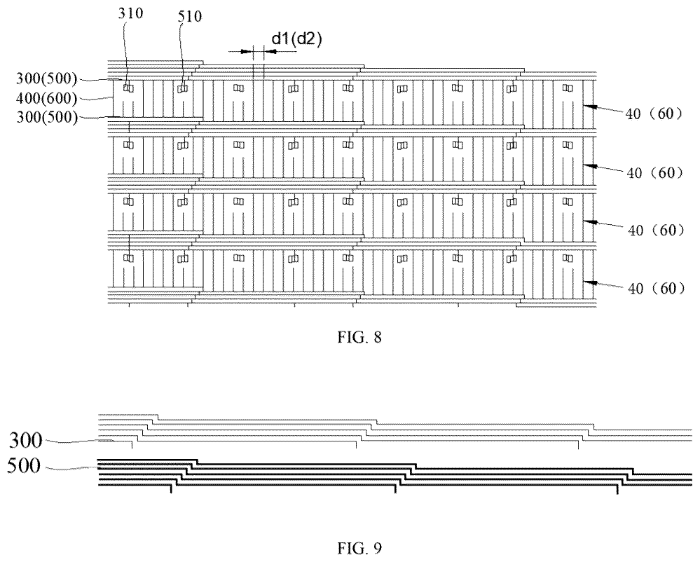

In one embodiment shown in FIG. 8 which is another enlarged top view of connection lines and filling lines in the display panel 10, in the thickness direction of the display panel 10, one first connection line 300 and one corresponding second connection line 500 may at least partially overlap. That is, an orthographic projection of the first connection line 300 on the substrate surface of the display panel 10 and the orthographic projection of the corresponding second connection line 500 on the substrate surface of the display panel 10 may at least partially overlap.

Optionally, in the thickness direction of the display panel 10, one first filling line 400 and one corresponding second filling line 600 may at least partially overlap. That is, the orthographic projection of the first filling line 400 on the substrate surface of the display panel 10 and the orthographic projection of the corresponding second filling line 600 on the substrate surface of the display panel 10 may at least partially overlap. Therefore, the first connection line 300 and the corresponding second connection line 500 at different film layers may at least partially overlap at their respective locations, and the first filling line 400 and the corresponding second filling line 600 at different film layers may at least partially overlap at their respective locations, which reduces the shielding of light and improves the light transmittance of the display panel 10.

Optionally, in the thickness direction of the display panel 10, the first connection line 300 and the corresponding second connection line 500 may at least partially overlap, and the first filling line 400 and the corresponding second filling line 600 may at least partially overlap.

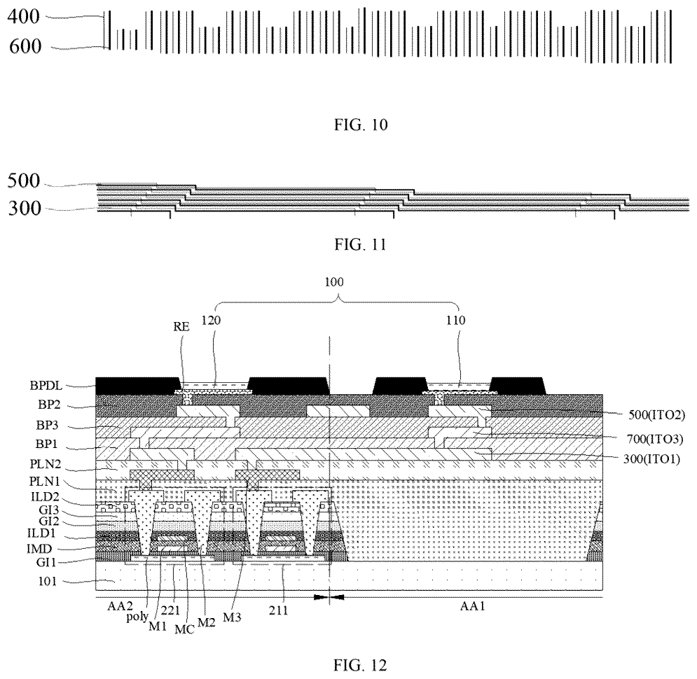

In one embodiment shown in FIG. 9 which is an enlarged top view of the first connection lines and the second connection lines in the display panel 10 and FIG. 10 which is an enlarged top view of the first filling lines and the second filling lines in the display panel 10, in the thickness direction, the first connection lines 300 and the second connection lines 500 may not overlap, as shown in FIG. 10, and the first filling lines 400 and the second filling lines 600 may not overlap. It should be noted that the line width difference in FIG. 9 and FIG. 10 is only to distinguish different types of lines, and does not represent the line width difference, and the line width difference in the following figures is also the same.

In another embodiment shown in FIG. 11 which is another enlarged top view of the first connection lines and the second connection lines in the display panel 10, in the thickness direction of the display panel 10, the first connection lines 300 and the second connection lines 500 may be at least partially spaced apart from each other. As shown in FIG. 9 and FIG. 11, there may be a certain gap between the orthographic projection of one first connection line 300 on the substrate surface of the display panel 10 and the orthographic projection of one corresponding second connection line 500 on the substrate surface of the display panel 10.

Optionally, in the thickness direction of the display panel 10, the first filling lines 400 and the second filling lines 600 may be at least partially spaced apart from each other. As shown in FIG. 10, there may be a certain gap between the orthographic projection of the first filling line 400 on the substrate surface of the display panel 10 and the orthographic projection of the corresponding second filling line 600 on the substrate surface of the display panel 10. Therefore, the first connection line 300 and the corresponding second connection line 500 may be staggered at different film layers, and the first filling line 400 and the corresponding second filling line 600 may be staggered at different film layers, thereby reducing electromagnetic interference between each other.

Optionally, in the thickness direction of the display panel 10, the first connection line 300 and the corresponding second connection line 500 may be at least partially spaced apart from each other, and the first filling line 400 and the corresponding second filling line 600 may be at least partially spaced apart from each other.

According to the different setting positions and arrangement modes of the first filling lines 400, the first filling lines 400 may be arranged in groups. Similarly, in some embodiments, optionally, the display panel 10 may include a plurality of first filling line groups 40, and each first filling line group 40 may include a plurality of first filling lines 400 arranged adjacent to each other and in parallel. The display panel 10 may also include a plurality of second filling line groups 60, and each second filling line group 60 may include a plurality of second filling lines 600 arranged adjacent to each other and in parallel.

As shown in FIG. 5 and FIG. 6, a plurality of second filling lines 600 located between the same two adjacent second connection lines 500 may be a group to form one second filling line group 60. The plurality of second filling lines 600 in one same second filling line group 60 may be arranged adjacent to each other and in parallel, and the intersection angles between these second filling lines 600 and the second connection lines 500 adjacent thereto may be also the same. In different second filling line groups 60, the number of second filling lines 600 in each group, the angle of intersection with the second connecting lines 500 adjacent thereto, the arrangement density of the second filling lines 600, etc. may be consistent or different. In other embodiments, the plurality of second filling lines 600 may be divided into more or fewer different second filling line groups 60 according to other different regularities, and the number of second filling lines 600 in each second filling line group 60 may also be different, which will not be described in detail here.

It should be noted that, compared with the embodiments in which only the first filling lines 400 are set in the aforementioned embodiment, when only the second filling lines 600 are set in the display panel 10 and the first filling lines 400 are not set, the second filling lines 600 of this embodiment may be regarded as the first filling lines 400 of the aforementioned embodiment, and the second connecting lines 500 of this embodiment may be regarded as the first connecting lines 300 of the aforementioned embodiment.

In some embodiments shown in FIG. 3 to FIG. 6, in one first filling line group 40, the spacing between any two adjacent first filling lines 400 is d1; in one second filling line group 60, the spacing between any two adjacent second filling lines 600 is d2; wherein d1 and d2 may be approximately equal or unequal.

In the second filling line group 60, the spacing d2 between any two adjacent second filling lines 600 may satisfy: 1 μm≤d2≤11 μm. For example, in one embodiment, the spacing d2 between any two adjacent second filling lines 600 in the same second filling line group 60 may be 1 μm, 1.6 μm, 2 μm, 3.4 μm, 5 μm, 8.7 μm, 10 μm, 10.2 μm, 11 μm, etc. The above data are only examples of the spacing d2 between any two adjacent second filling lines 600 in the second filling line group 60. In actual products, the spacing d2 between any two adjacent second filling lines 600 in the second filling line group 60 is not limited to the above data. The spacing d2 between any two adjacent second filling lines 600 and the spacing d1 between any two adjacent first filling lines 400 may be approximately equal or unequal, and may be flexibly adjusted according to different usage requirements in different scenarios.

As shown in Table 3 below, when only the second filling lines 600 are provided in the display panel 10, the first filling lines 400 are not provided, and the spacing between two adjacent second filling lines 600 in the second filling line group 60 is 2 μm, relative to the bare lens, the relative grayscale of the local position of the diffraction image in the horizontal direction may be 11.19%, and the relative grayscale of the local position in the vertical direction may be 10.66%. When only the second filling lines 600 are provided in the display panel 10, the first filling lines 400 are not provided, and the spacing between two adjacent second filling lines 600 in the second filling line group 60 is 5 μm, relative to the bare lens, the relative grayscale of the local position of the diffraction image in the horizontal direction may be 11.22%, and the relative grayscale of the local position in the vertical direction may be 11.09%. When only the second filling lines 600 are set in the display panel 10, the first filling lines 400 are not set, and the spacing between two adjacent second filling lines 600 in the second filling line group 60 is 10 μm, relative to the bare lens, the relative grayscale of the local position of the diffraction image in the horizontal direction may be 11.22%, and the relative grayscale of the local position in the vertical direction may be 11.45%.

TABLE 3
Relative diffraction strength after adding the second filling lines

| | Relative diffraction | Relative diffraction |
|---|---|---|
| | strength - | strength - Vertical |
| | Horizontal direction | direction |
| POL (AA1) | 10.62% | 9.54% |
| CFOT (AA1) | 11.26% | 11.85% |
| CFOT + Second filling lines | 11.22% | 11.45% |
| with 10 μm spacing (AA1) | | |
| CFOT + Second filling lines | 11.22% | 11.09% |
| with 5 μm spacing (AA1) | | |
| CFOT + Second filling lines | 11.19% | 10.66% |
| with 2 μm spacing (AA1) | | |

From the above, it can be seen that no matter the spacing between two adjacent second filling lines 600 in the plurality of second filling line groups 60 is 2 μm, 5 μm or 10 μm, relative to the bare lens, the difference in the relative grayscale of the local position of the image in the horizontal direction after diffraction and the relative grayscale of the local position of the image in the vertical direction after diffraction may be both reduced, indicating that the difference in the diffraction conditions of light in the horizontal and vertical directions may be reduced, thereby improving the display uniformity of the display panel 10.

As shown in Table 4, when the first filling lines 400 and the second filling lines 600 are simultaneously set in the display panel 10, and the spacing between two adjacent first filling lines 400 in the first filling line group 40 and two adjacent second filling lines 600 in the second filling line group 60 is 10 μm, relative to the bare lens, the relative grayscale of the local position of the diffraction image in the horizontal direction may be 11.19%, and the relative grayscale of the local position in the vertical direction may be 11.07%.

TABLE 4
Relative diffraction strength after adding the first filling line with
10 μm spacing the second filling lines with 10 μm spacing

| | Relative diffraction | Relative diffraction |
|---|---|---|
| | strength - | strength - Vertical |
| | Horizontal direction | direction |
| POL (AA1) | 10.62% | 9.54% |
| CFOT (AA1) | 11.26% | 11.85% |
| CFOT + First filling lines | 11.22% | 11.45% |
| with 10 μm spacing (AA1) | | |
| CFOT + Second filling lines | 11.22% | 11.45% |
| with 10 μm spacing (AA1) | | |
| CFOT + First filling lines | 11.19% | 11.07% |
| with 10 μm spacing + Second | | |
| filling lines with 10 μm spacing | | |
| (AA1) | | |

As shown in Table 5, when the first filling lines 400 and the second filling lines 600 are simultaneously set in the display panel 10, and the spacing between two adjacent first filling lines 400 in the first filling line group 40 and two adjacent second filling lines 600 in the second filling line group 60 is 5 μm, relative to the bare lens, the relative grayscale of the local position of the diffraction image in the horizontal direction may be 11.11%, and the relative grayscale of the local position in the vertical direction may be 10.68%.

TABLE 5
Relative diffraction strength after adding the first filling line with
5 μm spacing the second filling lines with 5 μm spacing

| | Relative diffraction | Relative diffraction |
|---|---|---|
| | strength - | strength - Vertical |
| | Horizontal direction | direction |
| POL (AA1) | 10.62% | 9.54% |
| CFOT (AA1) | 11.26% | 11.85% |
| CFOT + First filling lines | 11.23% | 11.11% |
| with 5 μm spacing (AA1) | | |
| CFOT + Second filling lines | 11.22% | 11.09% |
| with 5 μm spacing (AA1) | | |
| CFOT + First filling lines | 11.11% | 10.68% |
| with 5 μm spacing + Second | | |
| filling lines with 5 μm spacing | | |
| (AA1) | | |

As shown in Table 6, when the first filling lines 400 and the second filling lines 600 are simultaneously set in the display panel 10, the spacing between two adjacent first filling lines 400 in the first filling line group 40 is 2 μm, and the spacing between two adjacent second filling lines 600 in the second filling line group 60 is 5 μm, relative to the bare lens, the relative grayscale of the local position of the diffraction image in the horizontal direction may be 11.11%, and the relative grayscale of the local position in the vertical direction may be 10.24%.

TABLE 6
Relative diffraction strength after adding the first filling line with
2 μm spacing the second filling lines with 5 μm spacing

| | Relative diffraction | Relative diffraction |
|---|---|---|
| | strength - | strength - Vertical |
| | Horizontal direction | direction |
| POL (AA1) | 10.62% | 9.54% |
| CFOT (AA1) | 11.26% | 11.85% |
| CFOT + First filling lines | 11.14% | 10.59% |
| with 2 μm spacing (AA1) | | |
| CFOT + Second filling lines | 11.22% | 11.09% |
| with 5 μm spacing (AA1) | | |
| CFOT + First filling lines | 11.11% | 10.24% |
| with 2 μm spacing + Second | | |
| filling lines with 5 μm spacing | | |
| (AA1) | | |

As shown in Table 7, when the first filling lines 400 and the second filling lines 600 are simultaneously set in the display panel 10, and the spacing between two adjacent first filling lines 400 in the first filling line group 40 and two adjacent second filling lines 600 in the second filling line group 60 is 2 μm, relative to the bare lens, the relative grayscale of the local position of the diffraction image in the horizontal direction may be 11.05%, and the relative grayscale of the local position in the vertical direction may be 9.92%.

TABLE 7
Relative diffraction strength after adding the first filling line with
2 μm spacing the second filling lines with 2 μm spacing

| | Relative diffraction | Relative diffraction |
|---|---|---|
| | strength - | strength - Vertical |
| | Horizontal direction | direction |
| POL (AA1) | 10.62% | 9.54% |
| CFOT (AA1) | 11.26% | 11.85% |
| CFOT + First filling lines | 11.14% | 10.59% |
| with 2 μm spacing (AA1) | | |
| CFOT + Second filling lines | 11.19% | 10.66% |
| with 2 μm spacing (AA1) | | |
| CFOT + First filling lines | 11.05% | 9.92% |
| with 2 μm spacing + Second | | |
| filling lines with 2 μm spacing | | |
| (AA1) | | |

From the above, it can be seen that when the first filling lines 400 and the second filling lines 600 are simultaneously set in the display panel 10, and the spacing between two adjacent first filling lines 400 in the first filling line group 40 and two adjacent second filling lines 600 in the second filling line group 60 are 2 μm, the difference in the relative grayscale of the local position of the image in the horizontal direction after diffraction and the relative grayscale of the local position of the image in the vertical direction after diffraction may be the smallest, 0.12%, indicating that the difference in the diffraction conditions of light in the horizontal and vertical directions may be the smallest and the display uniformity of the display panel 10 may be the best.

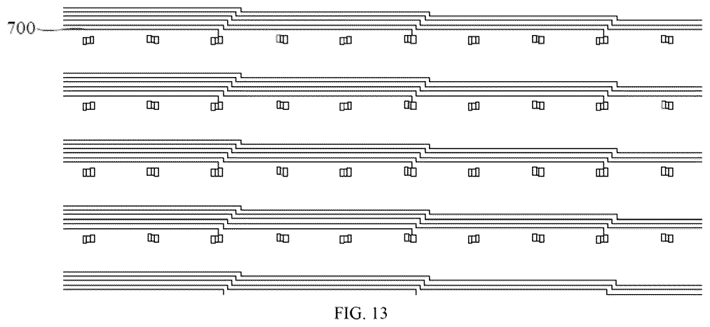

In one embodiment shown in FIG. 12 which is a cross-sectional view of the display panel 10 and FIG. 13 which is an enlarged top view of third connection lines 700 in the display panel 10, in conjunction with FIG. 1 and FIG. 2, the display panel 10 may also include a plurality of third connection lines 700.

In the thickness direction of the display panel 10, a film layer where the plurality of third connection lines 700 is located may be located between the film layer where the first connection lines 300 are located and the film layer where the second connection lines 500 are located, and the first connection lines 300 may be electrically connected to the second connection lines 500 via the plurality of third connection lines 700. The plurality of third connection lines 700 may be used as transition connection lines connecting the first connection lines 300 and the second connection lines 500.

As shown in FIG. 12, the display panel may further include a third insulating layer BP3. The third insulating layer BP3 may be located between the first insulating layer BP1 and the second insulating layer BP2. The third transparent conductive layer ITO3 may be located between the first insulating layer BP1 and the third insulating layer BP3. The third transparent conductive layer ITO3 may be electrically connected to the first transparent conductive layer ITO1 via through holes. The plurality of third connection lines 700 may be located in the third transparent conductive layer ITO3.

In some embodiments, optionally, two adjacent third connection lines 700 may be arranged at intervals from each other. No filling line may be provided between two adjacent third connection lines 700.

Since the length of the first filling lines 400 varies according to the different intervals between two adjacent first connecting lines 300, as shown in FIG. 3 and FIG. 4, in some embodiments, optionally, at least some of the first filling lines 400 may have different lengths.

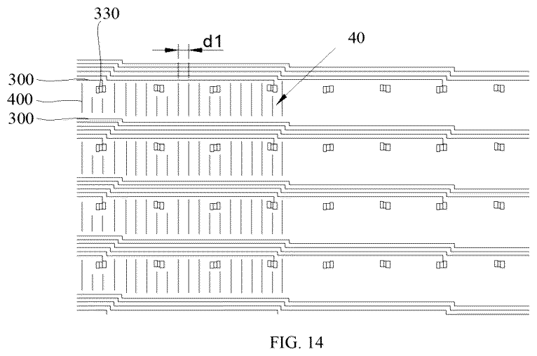

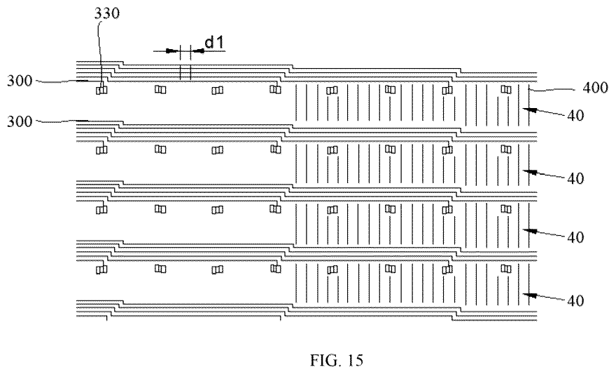

In some embodiments, as shown in FIG. 14 which is a schematic top view of a layout structure of the first filling lines 400 in a display panel 10 provided by the present disclosure and FIG. 15 which is another schematic top view of a layout structure of the first filling lines 400 in a display panel 10 provided by the present disclosure, along the direction perpendicular to the extension direction of the first connection lines 300, there may be a dense area with a relatively dense arrangement of the first connection lines 300, and a sparse area with a relatively sparse arrangement of the first connection lines 300. In the embodiment shown in FIG. 3, the extension direction of the first connection lines 300 may be the left-right direction. Along the vertical direction perpendicular to the left-right direction in FIG. 3, the left side of the figure may be a dense area where the first connection lines 300 are arranged relatively densely, and the right side of the figure may be a sparse area where the first connection lines 300 are arranged relatively sparsely. As shown in FIG. 3, in one embodiment, the first filling lines 400 may be set in both the dense area and the sparse area. As shown in FIG. 14, in another embodiment, the first filling lines 400 may be set only in the dense area. As shown in FIG. 15, in another embodiment, the first filling lines 400 may also be set only in the sparse area. The length of the part of the first filling lines 400 arranged in the dense area may be relatively short, and the length of the first filling lines 400 passing through the sparse area may be relatively long.

Similarly, as shown in FIG. 5, in some embodiments, the length of at least part of the second filling lines 600 may be different. Along the direction perpendicular to the extension direction of the second connecting lines 500, there may be a dense area with a relatively dense arrangement of the second connecting lines 500, and a sparse area with a relatively sparse arrangement of the second connecting lines 500. The second filling lines 600 may be arranged in both the dense area and the sparse area. In another embodiment, the second filling lines 600 may also be arranged only in the dense area. In another embodiment, the second filling lines 600 may also be arranged only in the sparse area. In the embodiment shown in FIG. 5, the extension direction of the second connecting lines 500 may be the left-right direction. Along the vertical direction perpendicular to the left-right direction in FIG. 5, the left side of the figure may be the dense area where the second connecting lines 500 are arranged relatively densely, and the length of the second filling lines 600 arranged in the dense area may be relatively short. The right side of the figure is the sparse area where the second connection lines 500 are arranged relatively sparsely, and the line length of the second filling lines 600 arranged in the sparse area may be relatively long.

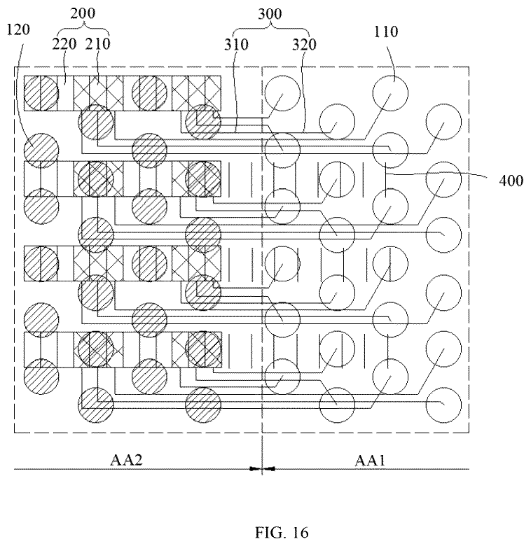

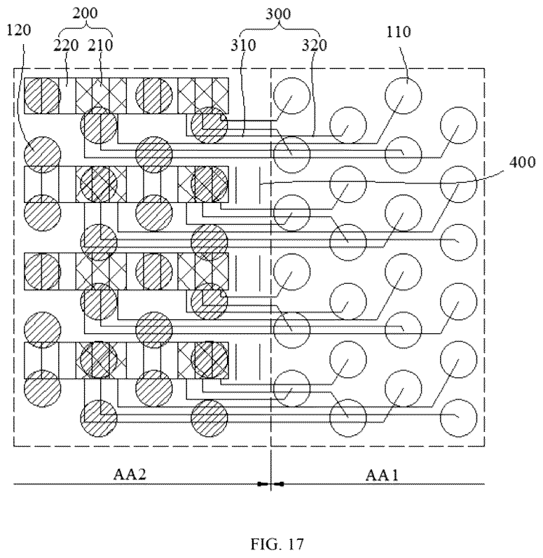

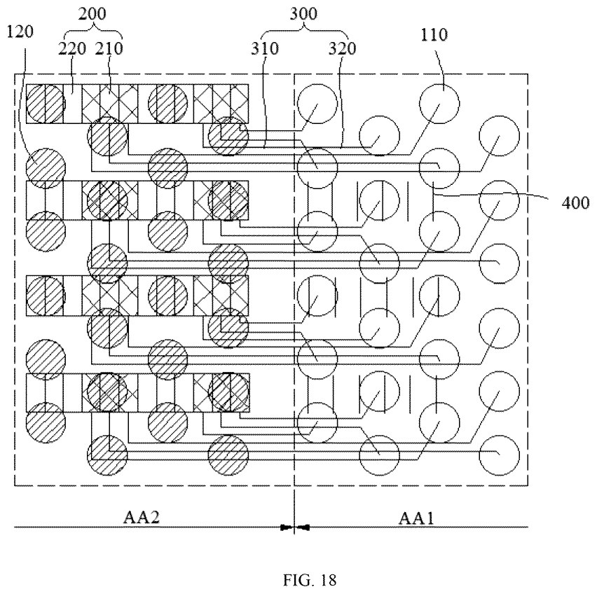

In some embodiments shown in FIG. 16 which is an enlarged view of a local area of a display panel 10 provided by the present disclosure, FIG. 17 is another enlarged view of a local area of an display panel 10 provided by the present disclosure, and FIG. 18 is another enlarged view of a local area of yet an display panel 10 provided by the present disclosure, optionally, one first connecting line 300 may include a first wiring 310 and a second wiring 320 disposed in the same layer and electrically connected to each other. The first wiring 310 may be at least partially located in the second display area AA2 and electrically connected to one corresponding first pixel circuit 210. The second wiring 320 may be at least partially located in the first display area AA1 and electrically connected to one corresponding first light-emitting element 110. As shown in FIG. 16, the first filling lines 400 may be disposed between at least a portion of two adjacent first wirings 310, and may be disposed between at least a portion of two adjacent second wirings 320, such that the reflection phase difference in different directions caused by the first connecting lines in the first display area AA1 and the second display area AA2 is balanced and the display uniformity and the display effect are improved. As shown in FIG. 17, in another embodiment, the first filling lines 400 may be provided only between at least two adjacent second wirings 320, thereby increasing the wiring density of the second display area AA2, improving the device performance in the area, and improving the display effect of the second display area AA2. As shown in FIG. 18, the first filling lines 400 may be provided only between two adjacent first wirings 310, thereby further reducing the diffraction intensity of the first display area AA1 in the vertical direction, reducing the diffraction difference in the horizontal direction, and effectively improving the diffraction and the display effect of the first display area AA1. One first connecting line 300 may be electrically connected to one corresponding first pixel circuit 210 through one corresponding first wiring 310, and one first connecting line 300 may be electrically connected to one corresponding first light-emitting element 110 through one corresponding second wiring 320, to electrically connect the corresponding first light-emitting element 110 to the corresponding first pixel circuit 210.

In one embodiment, the first wiring 310 and the second wiring 320 may be made of light-transmitting conductive materials, respectively. In another embodiment, the first wiring 310 may be a metal wire segment with low resistance, and the second wiring 320 may be a light-transmitting wire segment.

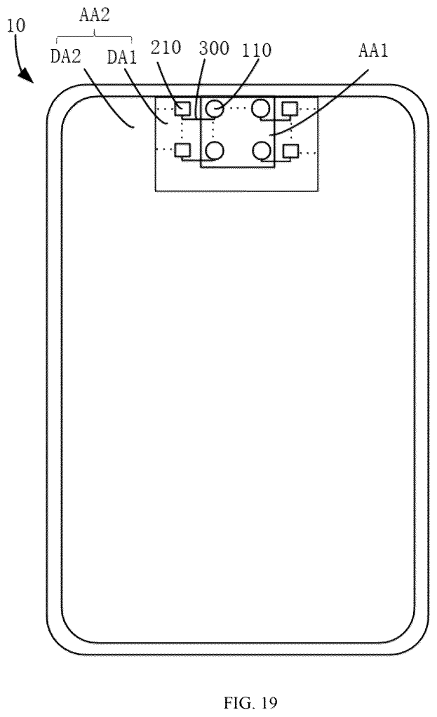

In some embodiments shown in FIG. 19 which is a structure of another display panel 10 provided by the present disclosure, the second display area AA2 may include a transition area DA1 and a sub-display area DA2. The transition area DA1 may be located between the sub-display area DA2 and the first display area AA1.

The first pixel circuits 210 may be located in the transition area DA1. Since the transition area DA1 is located between the sub-display area DA2 and the first display area AA1, and the first pixel circuits 210 may be arranged in the transition area DA1, the length of the first connection lines 300 may be reduced, which is beneficial to reducing the voltage drop of the electrical signal on the first connection lines 300 and reducing the wiring area in the second display area AA2. The light transmittance of the second display area AA2 may be improved.

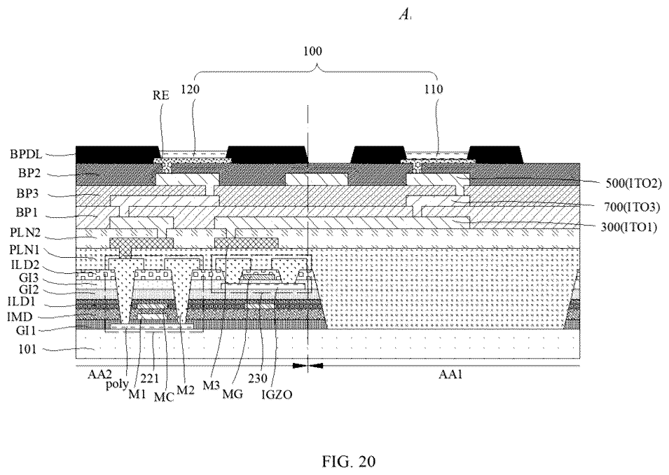

In some embodiments shown in FIG. 20 which is another cross-sectional view of a display panel 10 provided by the present disclosure, the display panel 10 may further include a substrate 101, a low-temperature polysilicon active layer poly, a first gate insulating layer GI1, a first metal layer M1, a capacitor insulating layer IMD, a capacitor metal layer MC, a first interlayer insulating layer ILD1, a second gate insulating layer GI2, a metal oxide active layer IGZO, a third gate insulating layer GI3, a second interlayer insulating layer ILD2, a second metal layer M2, a third metal layer M3, a fourth metal layer MG, a first planarization layer PLN1, a second planarization layer PLN2, a first insulating layer BP1, a second insulating layer BP2, a third insulating layer BP3, a first transparent conductive layer ITO1, a second transparent conductive layer ITO2, a third transparent conductive layer ITO3, an anode RE, and a black pixel definition layer BPDL.

The substrate 101 may at least include a substrate, for example, may include a substrate and a buffer layer. The first gate insulating layer GI1, the capacitor insulating layer IMD, the first interlayer insulating layer ILD1, the second gate insulating layer GI2, the third gate insulating layer GI3, the second interlayer insulating layer ILD2, the first planarizing layer PLN1, the second planarizing layer PLN2, the first insulating layer BP1, the second insulating layer BP2, the third insulating layer BP3 and the black pixel definition layer BPDL may be sequentially stacked on the substrate 101. The low-temperature polysilicon active layer poly may be located between the substrate 101 and the first gate insulating layer GI1. The first metal layer M1 may be located between the first gate insulating layer GI1 and the capacitor insulating layer IMD. The capacitor metal layer MC may be located between the capacitor insulating layer IMD and the first interlayer insulating layer ILD1. The metal oxide active layer IGZO may be located between the second gate insulating layer GI2 and the third gate insulating layer GI3. The fourth metal layer MG may be located between the third gate insulating layer GI3 and the second interlayer insulating layer ILD2. The second metal layer M2 may be located between the second interlayer insulating layer ILD2 and the first planarizing layer PLN1, and the second metal layer M2 may be provided with metal through holes to be electrically connected to the low-temperature polysilicon active layer poly. The third metal layer M3 may be located between the first planarizing layer PLN1 and the second planarizing layer PLN2, and the third metal layer M3 may be provided with metal through holes to be electrically connected to the second metal layer M2. The first transparent conductive layer ITO1 may be located between the second planarizing layer PLN2 and the first insulating layer BP1, and the first transparent conductive layer ITO1 may be electrically connected to the third metal layer M3 via through holes. The second transparent conductive layer ITO2 may be located between the first insulating layer BP1 and the second insulating layer BP2, and the second transparent conductive layer ITO2 may be electrically connected to the first transparent conductive layer ITO1 via through holes. The third transparent conductive layer ITO3 may be located between the second insulating layer BP2 and the third insulating layer BP3, and the third transparent conductive layer ITO3 may be electrically connected to the second transparent conductive layer ITO2 via through holes.

The first connection lines 300 and the first filling lines 400 may be located in the first transparent conductive layer ITO1, the second connection lines 500 and the second filling lines 600 may be located in the third transparent conductive layer ITO3, and the third connection lines 700 may be located in the second transparent conductive layer ITO2. The black pixel definition layer BPDL may define pixel ports, and the light emitting elements 100 may be located in the pixel port. The light emitting elements 100 may be electrically connected to the second connection lines 500 through the anode RE. The pixel ports may include first pixel ports and second pixel ports. The first pixel ports may be located in the first display area AA1, and the second pixel ports may be located in the second display area AA2. The first light emitting elements 110 may be located in the first pixel ports, and the second light emitting elements 120 may be located in the second pixel port.

It should be noted that, corresponding to the above-mentioned embodiments, one pixel circuit 200 of the display panel may include a low-temperature polysilicon transistor 221 and a metal oxide transistor 230. The third metal layer M3 may be connected to the low-temperature polysilicon transistor 221 through the second metal layer M2.

In another embodiment, the display panel may also be a display panel designed with LTPS (Low Temperature Poly-Silicon). Correspondingly, one pixel circuit 200 of the display panel may include a low-temperature polysilicon transistor 221, and the third metal layer M3 may be connected to the low-temperature polysilicon transistor 221 through the second metal layer M2.

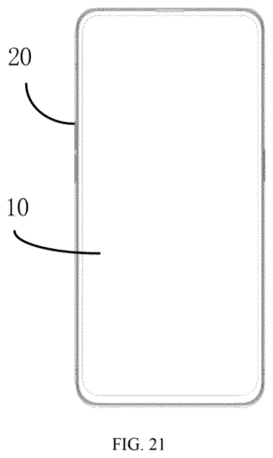

The present disclosure also provides a display device. As shown in FIG. 21 which is a display device provided by the present disclosure, the display device 20 may include a display panel 10 provided by various embodiments of the present disclosure. The display device 20 may also have benefits of the display panel 10 provided by various embodiments of the present disclosure, and for the details, references may be made to the above description about the display panel 10.

In one embodiment, the display device 20 may be a mobile phone shown in FIG. 21. In other embodiments, the display device may be any electronic product with display function, including but not limited to, a television, a laptop computer, a desktop computer, a tablet, a digital camera, a smart bracelet, smart glasses, a vehicle display, an industrial control device, a medical display panel, a touch interaction terminal, and so on. The present disclosure has no limit on this.

In the present disclosure, relational terms such as “first” and “second” are only used to distinguish one entity or operation from another entity or operation, and do not necessarily require or imply that there is a relationship between these entities or operations. There is no such actual relationship or sequence. Furthermore, the terms “comprises”, “include”, or any other variations thereof are intended to cover a non-exclusive inclusion such that a process, method, article, or apparatus that includes a list of elements includes not only those elements, but also those not expressly listed, or elements inherent to the process, method, article or equipment. Without further limitation, an element defined by the statement “comprises a . . . ” does not exclude the presence of additional identical elements in a process, method, article, or apparatus that includes the stated element.

Various embodiments have been described to illustrate the operation principles and exemplary implementations. It should be understood by those skilled in the art that the present disclosure is not limited to the specific embodiments described herein and that various other obvious changes, rearrangements, and substitutions will occur to those skilled in the art without departing from the scope of the disclosure. Thus, while the present disclosure has been described in detail with reference to the above described embodiments, the present disclosure is not limited to the above described embodiments, but may be embodied in other equivalent forms without departing from the scope of the present disclosure, which is determined by the appended claims.

What is claimed is:

1. A display panel, comprising:
a first display area and a second display area, wherein the second display area at least partially surrounds the first display area and light transmittance of the first display area is larger than light transmittance of the second display area;
light-emitting elements including first light-emitting elements disposed in the first display area;
pixel circuits including first pixel circuits disposed in the second display area, wherein the first pixel circuits are used to drive the first light-emitting elements to emit light;
a plurality of first connecting lines, wherein one first light-emitting element and one corresponding first pixel circuit are electrically connected through a corresponding one of the plurality of first connecting lines; and
a plurality of first filling lines disposed in a layer same as the plurality of first connecting lines, wherein the plurality of first filling lines is located between at least a portion of two adjacent first connecting lines, and an extension direction of the plurality of first filling lines intersects with an extension direction of the plurality of first connecting lines.

2. The display panel according to claim 1, wherein:
the plurality of first filling lines forms a plurality of first filling line groups, and one of the plurality of first filling line groups includes multiple first filling lines of the plurality of first filling lines that are adjacent and parallel to each other.

3. The display panel according to claim 2, wherein:
in the plurality of first filling line group, a distance between any two adjacent first filling lines is d1, and 1 μm≤d1≤11 μm.

4. The display panel according to claim 2, wherein:
in the plurality of first filling line group, a distance between any two adjacent first filling lines is same.

5. The display panel according to claim 2, wherein:
in the plurality of first filling line group, a distance between any two adjacent first filling lines is one of 2 μm, 5 μm, or 10 μm.

6. The display panel according to claim 1, further including a plurality of second connection lines and a plurality of second filling lines, wherein:
the plurality of second connection lines is electrically connected to the plurality of first connection lines;
one first light-emitting element and one corresponding first pixel circuit are electrically connected through a corresponding one of the plurality of first connection lines and a corresponding one of the plurality of second connection lines; and
the plurality of second filling lines is arranged in a layer same as the plurality of second connection lines and is located between at least a portion of two adjacent first connecting lines.

7. The display panel according to claim 6, wherein:
in a thickness direction of the display panel, one of the plurality of first connecting lines at least partially overlaps with a corresponding one of the plurality of second connecting lines; and/or
in the thickness direction of the display panel, one of the plurality of first filling lines at least partially overlaps with a corresponding one of the plurality of second filling lines.

8. The display panel according to claim 6, wherein:
in a thickness direction of the display panel, one of the plurality of first connecting lines and a corresponding one of the plurality of second connecting lines are at least partially spaced apart from each other; and/or
in the thickness direction of the display panel, one of the plurality of first filling lines and a corresponding one of the plurality of second filling lines are at least partially spaced apart from each other.

9. The display panel according to claim 6, wherein:
the plurality of first filling lines forms a plurality of first filling line groups, wherein one of the plurality of first filling line groups includes multiple first filling lines of the plurality of first filling lines that are adjacent and parallel to each other; and
the plurality of second filling lines forms a plurality of second filling line groups, wherein one of the plurality of second filling line groups includes multiple second filling lines of the plurality of second filling lines that are adjacent and parallel to each other.

10. The display panel according to claim 9, wherein:
in the plurality of first filling line group, a distance between any two adjacent first filling lines is d1;
in the plurality of second filling line group, a distance between any two adjacent second filling lines is d2; and
d1 is equal to or different from d2.

11. The display panel according to claim 6, further including a plurality of third connection lines, wherein:
in the thickness direction of the display panel, a film layer where the plurality of third connecting lines is located is located between a film layer where the plurality of first connecting lines is located and a film layer where the plurality of second connecting lines is located; and
one of the plurality of first connecting lines is electrically connected to a corresponding one of the plurality of second connecting lines via a corresponding one of the plurality of third connecting lines.

12. The display panel according to claim 1, wherein:
at least some of the plurality of first filling lines have different lengths.

13. The display panel according to claim 1, wherein:
along a direction perpendicular to an extension direction of the plurality of first connecting lines, there are a dense area with relatively dense arrangement of the plurality of first connecting lines and a sparse area with relatively sparse arrangement of the plurality of first connecting lines; and
the plurality of first filling lines is arranged in the dense area and/or the plurality of first filling lines is arranged in the sparse area.

14. The display panel according to claim 1, wherein:
one first connecting line of the plurality of first connecting lines includes a first routing line and a second routing line which are arranged in a same layer and are electrically connected to each other, wherein the first routing line is at least partially located in the second display area and is electrically connected to one corresponding first pixel circuit; and the second routing line is at least partially located in the first display area and is electrically connected to one corresponding first light-emitting element; and
the plurality of first filling lines is arranged between at least a portion of two adjacent first routing lines; and/or the plurality of first filling lines is arranged between at least a portion of two adjacent second routing lines.

15. A display device comprising a display panel, wherein:
the display panel includes:
a first display area and a second display area, wherein the second display area at least partially surrounds the first display area and light transmittance of the first display area is larger than light transmittance of the second display area;
light-emitting elements including first light-emitting elements disposed in the first display area;
pixel circuits including first pixel circuits disposed in the second display area, wherein the first pixel circuits are used to drive the first light-emitting elements to emit light;
a plurality of first connecting lines, wherein one first light-emitting element and one corresponding first pixel circuit are electrically connected through a corresponding one of the plurality of first connecting lines; and
a plurality of first filling lines disposed in a layer same as the plurality of first connecting lines, wherein the plurality of first filling lines is located between at least a portion of two adjacent first connecting lines, and an extension direction of the plurality of first filling lines intersects with an extension direction of the plurality of first connecting lines.
